(19) United States
(12) Patent Application Publication
(10) Pub. No.: US 2026/0036621 A1
(43) Pub. Date: Feb. 5, 2026

(54) AUTOMATICALLY MAPPING EVENT-BASED SIMULATION DATA TO CYCLE-BASED SIMULATION IN HYBRID HARDWARE DEBUG PLATFORMS

(71) Applicant: International Business Machines Corporation, Armonk, NY (US)

(72) Inventors: Melchizedek Das, Paradeep (IN); Sampath Goud Baddam, CV Ramannager (IN); Arun Joseph, Whitefield (IN); Joachim Heiner Paret, Ehningen (DE); Wolfgang Roesner, Austin, TX (US)

(21) Appl. No.: 18/788,224

(22) Filed: Jul. 30, 2024

(51) Int. Cl. G01R 31/317; G01R 31/3183

(52) U.S. Cl. CPC G01R 31/31705; G01R 31/318357

(57) ABSTRACT

A computer-implemented method is provided. Aspects include receiving first waveform data of a first format, wherein the first waveform data includes event-based simulation data. Aspects include generating second waveform data of a second format based on the first waveform data, wherein the second waveform data is compatible with a cycle-based simulation environment. Aspects include performing one or more debugging operations by processing the second waveform data within the cycle-based simulation environment.

### BACKGROUND

The present disclosure generally relates to event-based simulation data, and more specifically, to automatically mapping event-based simulation data to cycle-based simulation in hybrid hardware debug platforms.

Various feature-rich tools are available for simulating an integrated circuit (IC) design (e.g., an application specific integrated circuit (ASIC) design) in association with verifying the IC design prior to fabrication. For example, some approaches may use cycle-based simulation or event-based simulation in association with verifying the IC design.

Cycle-based simulation (also referred to herein as cycle simulation) is a technique for digital circuit simulation which computes the steady state response of a circuit at each clock cycle. Cycle-based simulation does not simulate detailed circuit timing. Rather, for example, cycle-based simulation provides circuit signals with respect to each clock cycle. Cycle-based simulation evaluates the logic between state elements and/or ports per cycle. For example, each logic element is evaluated once per cycle, which may support increases in simulation speed. Cycle-based simulators are compatible with simulating synchronous logic designs.

Event-based simulation (also referred to herein as event simulation) is a technique for digital circuit simulation which is based on events in logic. In event-based simulation, when there is change in a input event, the output in response to the input event is evaluated. For example, event-based simulators may operate by propagating events through a design. Event-based simulation is relatively slow compared to cycle-based simulation. For example, while event-based simulation may provide a highly accurate simulation environment, the speed of the execution depends on the size of the design associated with the simulation and the level of activity within the simulation. Verilog-XL is an example of an event based simulator.

### SUMMARY

Embodiments of the present disclosure are directed to computer implemented methods for automatically mapping event-based simulation data to cycle-based simulation in hybrid hardware debug platforms.

Example embodiments of the present disclosure are directed to a computer-implemented method including: receiving first waveform data of a first format, wherein the first waveform data includes event-based simulation data; generating second waveform data of a second format based on the first waveform data, wherein the second waveform data is compatible with a cycle-based simulation environment; and performing one or more debugging operations by processing the second waveform data within the cycle-based simulation environment.

Example embodiments of the present disclosure include a computing system having a memory having computer readable instructions and one or more processors for executing the computer readable instructions. The computer readable instructions controlling the one or more processors to perform operations that include: receiving first waveform data of a first format, wherein the first waveform data includes event-based simulation data; generating second waveform data of a second format based on the first waveform data, wherein the second waveform data is compatible with a cycle-based simulation environment; and performing one or more debugging operations by processing the second waveform data within the cycle-based simulation environment.

Example embodiments of the present disclosure include a computer program product having a computer readable storage medium having program instructions embodied therewith. The program instructions executable by a processor to cause the processor to perform operations that include: receiving first waveform data of a first format, wherein the first waveform data includes event-based simulation data; generating second waveform data of a second format based on the first waveform data, wherein the second waveform data is compatible with a cycle-based simulation environment; and performing one or more debugging operations by processing the second waveform data within the cycle-based simulation environment.

Other embodiments of the present disclosure implement features of the above-described method in computer systems and computer program products.

Additional technical features and benefits are realized through the techniques of the present disclosure. Embodiments and aspects of the disclosure are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the present disclosure are apparent from the following detailed description taken in conjunction with the accompanying drawings.

FIG. 1 illustrates a block diagram of an example computer system for use in conjunction with one or more embodiments of the present disclosure.

FIG. 2 illustrates an example timing diagram illustrative of differences between cycle-based simulation and event-based simulation.

FIG. 3 depicts a flow diagram supportive of hardware logic design and debug in accordance with one or more embodiments of the present disclosure.

FIG. 4 depicts a flow diagram illustrating a platform which supports automatically mapping event-based simulation data to cycle-based simulation in accordance with one or more embodiments of the present disclosure.

FIG. 5 illustrates an example flowchart of a method that supports automatically mapping event-based simulation data to cycle-based simulation in hybrid hardware debug platforms in accordance with one or more embodiments of the present disclosure.

FIG. 6 illustrates an example timing diagram associated with automatically mapping event-based simulation data to cycle-based simulation in hybrid hardware debug platforms in accordance with one or more embodiments of the present disclosure.

FIG. 7 illustrates an example workflow associated with designing and debugging an IC design in accordance with one or more embodiments of the present disclosure.

FIG. 8 illustrates an example a hybrid hardware debugging platform in accordance with one or more embodiments of the present disclosure.

FIG. 9 illustrates an example flowchart of a method that supports automatically mapping event-based simulation data to cycle-based simulation in hybrid hardware debug platforms in accordance with one or more embodiments of the present disclosure.

### DETAILED DESCRIPTION

Embodiments of the present disclosure are directed to computer implemented methods for automatically mapping event-based simulation data to cycle-based simulation in hybrid hardware debug platforms.

Example embodiments of the present disclosure are directed to a computer-implemented method including: receiving first waveform data of a first format, wherein the first waveform data includes event-based simulation data; generating second waveform data of a second format based on the first waveform data, wherein the second waveform data is compatible with a cycle-based simulation environment; and performing one or more debugging operations by processing the second waveform data within the cycle-based simulation environment. The computer-implemented method provides advantages of effective debugging through technical improvements which include conversion of event-based simulation data (i.e., in which events are time granular, and the data is incompatible with a cycle-based simulation environment) to equivalent cycle-based simulation data for debugging.

Example embodiments of the present disclosure include a computing system having a memory having computer readable instructions and one or more processors for executing the computer readable instructions. The computer readable instructions controlling the one or more processors to perform operations that include: receiving first waveform data of a first format, wherein the first waveform data includes event-based simulation data; generating second waveform data of a second format based on the first waveform data, wherein the second waveform data is compatible with a cycle-based simulation environment; and performing one or more debugging operations by processing the second waveform data within the cycle-based simulation environment. The operations provide advantages of effective debugging through technical improvements which include conversion of event-based simulation data (i.e., in which events are time granular, and the data is incompatible with a cycle-based simulation environment) to equivalent cycle-based simulation data for debugging.

Example embodiments of the present disclosure include a computer program product having a computer readable storage medium having program instructions embodied therewith. The program instructions executable by a processor to cause the processor to perform operations that include: receiving first waveform data of a first format, wherein the first waveform data includes event-based simulation data; generating second waveform data of a second format based on the first waveform data, wherein the second waveform data is compatible with a cycle-based simulation environment; and performing one or more debugging operations by processing the second waveform data within the cycle-based simulation environment. The operations provide advantages of effective debugging through technical improvements which include conversion of event-based simulation data (i.e., in which events are time granular, and the data is incompatible with a cycle-based simulation environment) to equivalent cycle-based simulation data for debugging.

In addition to one or more of the features described herein, generating the second waveform data includes transforming the first waveform data to the second waveform data by sampling signal waveforms included in the first waveform data according to a sampling rate. The sampling operations provide advantages and technical improvements that support effective mapping between the first waveform data (i.e., in which events are time granular, and the data is incompatible with a cycle-based simulation environment) and the second waveform data (i.e., in which events are at clock edges and are compatible with the cycle-based simulation environment), thus providing waveform data with which a designer is more familiar and based on which the designer may effectively debug an integrated circuit design.

In addition to one or more of the features described herein, the methods and operations include: selecting a target abstraction level from among a set of candidate abstraction levels associated with transforming the first waveform data to the second waveform data, based on a parameter, wherein the parameter is selected from the group consisting of: a temporal parameter associated with transforming the first waveform data into the second waveform data; and a data preservation parameter associated with transforming the first waveform data into the second waveform data; and determining the sampling rate based on the target abstraction level. The operations provide advantages and technical improvements that support various levels of abstractions for determining the sampling rate. Determining the sampling rate based on a target abstraction level for transforming the event-based simulation data to the cycle-based simulation data supports balancing between an amount of time for completing the conversion from the event-based simulation data to the cycle-based simulation data and data preservation in association with the conversion.

In addition to one or more of the features described herein, determining the sampling rate is based on a first abstraction level among the set of candidate abstraction levels and includes: identifying, for at least two signal waveforms included in the first waveform data, a target quantity of events associated with each of the at least two signal waveforms; calculating, for each of the at least two signal waveforms included in the first waveform data, a temporal duration between two consecutive events included among the target quantity of events; and selecting, as the sampling rate, a smallest temporal duration among the temporal durations. Determining the sampling rate based on a target abstraction level for transforming the event-based simulation data to the cycle-based simulation data supports balancing between an amount of time for completing the conversion from the event-based simulation data to the cycle-based simulation data and data preservation in association with the conversion.

In addition to one or more of the features described herein, determining the sampling rate is based on a first abstraction level among the set of candidate abstraction levels and includes an assumption that a fastest clock among signal waveforms included in the first waveform data can be used as the sampling rate. The operations provide advantages and technical improvements that support tuning the sampling rate in association with transforming the first waveform data into the second waveform data.

In addition to one or more of the features described herein, determining the sampling rate is based on a second abstraction level among the set of candidate abstraction levels and includes: identifying, for at least two signal waveforms included in the first waveform data, all events associated with each of the at least two signal waveforms; calculating, for each of the at least two signal waveforms included in the first waveform data, a temporal duration between two consecutive events included among all the events; and selecting, as the sampling rate, a smallest temporal duration among the temporal durations. Determining the sampling rate based on a target abstraction level for transforming the event-based simulation data to the cycle-based simulation data supports balancing between an amount of time for completing the conversion from the event-based simulation data to the cycle-based simulation data and data preservation in association with the conversion.

In addition to one or more of the features described herein, determining the sampling rate is based on a second abstraction level among the set of candidate abstraction levels and includes an assumption that there is no skew between events across signal waveforms included in the first waveform data. The operations provide advantages and technical improvements that support trading a loss of skew information in exchange for reduced processing time in association with transforming the event-based simulation data to the cycle-based simulation data.

In addition to one or more of the features described herein, determining the sampling rate is based on a third abstraction level among the set of candidate abstraction levels and includes: identifying, for at least two signal waveforms included in the first waveform data, all events associated each of the at least two signal waveforms; calculating temporal durations across events respectively associated with the at least two signal waveforms; and selecting, as the sampling rate, a smallest temporal duration among the temporal durations, wherein the smallest temporal duration is between a first event associated with a first signal waveform and a second event associated with a second signal waveform. Determining the sampling rate based on a target abstraction level for transforming the event-based simulation data to the cycle-based simulation data supports balancing between an amount of time for completing the conversion from the event-based simulation data to the cycle-based simulation data and data preservation in association with the conversion.

In addition to one or more of the features described herein, the temporal parameter is a target temporal duration associated with transforming the first waveform data into the second waveform data. The operations provide advantages and technical improvements that support adjusting the amount of time to be incurred in association with transforming the first waveform data into the second waveform data.

In addition to one or more of the features described herein, the data preservation parameter is associated with preserving skew information associated with signal waveforms included in the first waveform data. The operations provide advantages and technical improvements that support adjusting the amount of information (e.g., skew information) to be preserved or omitted in association with transforming the first waveform data into the second waveform data.

Various aspects of the present disclosure are described by narrative text, flowcharts, block diagrams of computer systems, and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

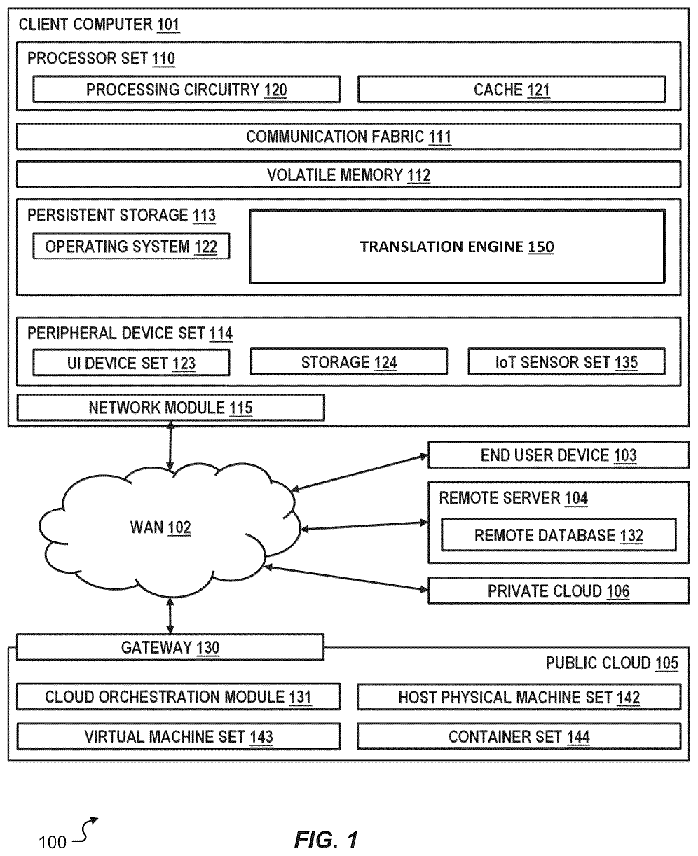

Referring now to FIG. 1, computing environment 100 contains an example of an environment for the execution of at least some of the computer code involved in performing the inventive methods, such as automatically mapping, using translation engine 150, event-based simulation data to cycle-based simulation in hybrid hardware debug platforms. In addition to translation engine 150, computing environment 100 includes, for example, computer 101, wide area network (WAN) 102, end user device (EUD) 103, remote server 104, public Cloud 105, and private Cloud 106. In this embodiment, computer 101 includes processor set 110 (including processing circuitry 120 and cache 121), communication fabric 111, volatile memory 112, persistent storage 113 (including operating system 122 and translation engine 150, as identified above), peripheral device set 114 (including user interface (UI), device set 123, storage 124, and Internet of Things (IoT) sensor set 135), and network module 115. Remote server 104 includes remote database 132. Public Cloud 105 includes gateway 130, Cloud orchestration module 131, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 132. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a Cloud, even though it is not shown in a Cloud in FIG. 1. On the other hand, computer 101 is not required to be in a Cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in translation engine 150 in persistent storage 113.

COMMUNICATION FABRIC 111 is the signal conduction paths that allow the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, the volatile memory is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface type operating systems that employ a kernel. The code included in translation engine 150 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 135 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collects and store helpful and useful data for use by other computers, such as computer 101. For example, in a hypothetical case where computer 101 is designed and programmed to provide a recommendation based on historical data, then this historical data may be provided to computer 101 from remote database 132 of remote server 104.

PUBLIC CLOUD 105 is any computer system available for use by multiple entities that provides on-demand availability of computer system resources and/or other computer capabilities, especially data storage (Cloud storage) and computing power, without direct active management by the user. Cloud computing typically leverages sharing of resources to achieve coherence and economies of scale. The direct and active management of the computing resources of public Cloud 105 is performed by the computer hardware and/or software of Cloud orchestration module 131. The computing resources provided by public Cloud 105 are typically implemented by virtual computing environments that run on various computers making up the computers of host physical machine set 142, which is the universe of physical computers in and/or available to public Cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 131 manages the transfer and storage of images, deploys new instantiations of VCEs and manages active instantiations of VCE deployments. Gateway 130 is the collection of computer software, hardware, and firmware that allows public Cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public Cloud 105, except that the computing resources are only available for use by a single enterprise. While private Cloud 106 is depicted as being in communication with WAN 102, in other embodiments a private Cloud may be disconnected from the internet entirely and only accessible through a local/private network. A hybrid Cloud is a composition of multiple Clouds of different types (for example, private, community or public Cloud types), often respectively implemented by different vendors. Each of the multiple Clouds remains a separate and discrete entity, but the larger hybrid Cloud architecture is bound together by standardized or proprietary technology that enables orchestration, management, and/or data/application portability between the multiple constituent Clouds. In this embodiment, public Cloud 105 and private Cloud 106 are both part of a larger hybrid Cloud.

A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

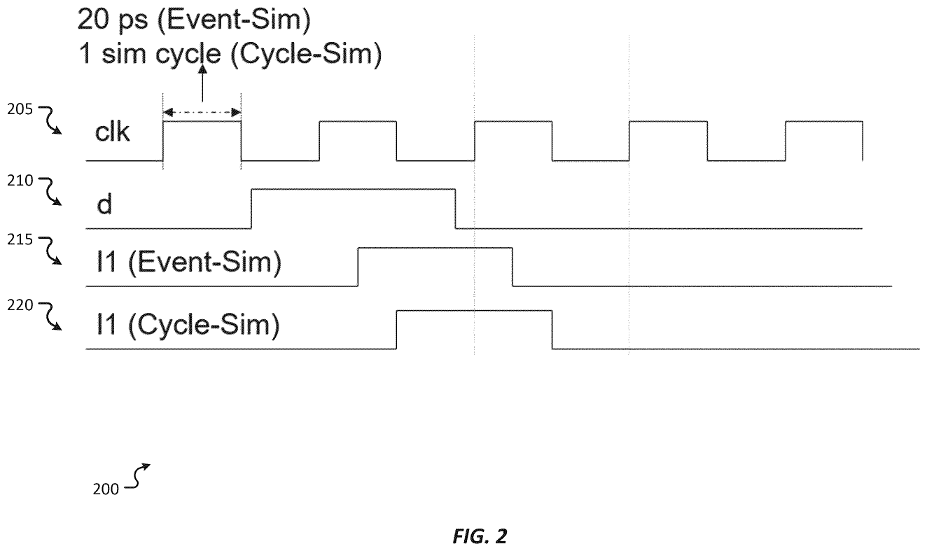

FIG. 2 illustrates an example timing diagram 200 illustrative of some differences between cycle-based simulation and event-based simulation.

The timing diagram 200 illustrates waveforms of a clock signal 205 (‘clk’), a data signal 210 (‘d’), an output signal 215 (‘I1 (Event-Sim)’) associated with event-based simulation, and an output signal 220 (‘I1 (Cycle-Sim)’) associated with cycle-based simulation.

With respect to event-based simulation, time advances in concrete steps (e.g., variable width steps). In event-based simulation, events (also referred to herein as transitions) can occur at any time and are not limited to being aligned with the clock signal 205. Event-based simulation supports a time granularity with which events occur. For example, with reference to the timing diagram 200 of FIG. 2, events associated with event-based simulation occur every 20 picoseconds (ps), but the time granularity is not limited thereto.

With respect to cycle-based simulation, time advances at clock edges of the clock signal 205. In cycle-based simulation, events occur at the clock edges of the clock signal 205. In cycle-based simulation, delays (clock skew) in terms of concrete time are ignored. For example, with reference to output signal 220 and the timing diagram 200 of FIG. 2, events associated with output signal 220 and cycle-based simulation occur at a rising clock edge (also referred to herein as an uptick) or a falling clock edge (also referred to herein as a downtick) of the clock signal 205. The upticks and downticks may collectively be referred to as “simticks.” Data generated by cycle-based simulation has transitions at a “simtick” granularity.

Systems and techniques are described herein which support effective conversion of event-based simulation data (i.e., in which events are time granular) to equivalent cycle-based simulation data (i.e., in which events are at clock edges), example aspects of which are described herein. For example, the systems and techniques described herein which support effective conversion of event-based waveform data (i.e., in which events are time granular) to equivalent cycle-based waveform data (i.e., in which events are at clock edges), example aspects of which are described herein. The systems and techniques described herein support determining a sampling rate at which to sample the event-based simulation data, and further, converting the event-based simulation data to cycle-based simulation data by sampling the event-based simulation data according to the sampling rate.

Aspects of the techniques described herein support various levels of abstractions for determining the sampling rate. The techniques described herein include determining the sampling rate based on a target abstraction level for transforming the event-based simulation data to the cycle-based simulation data, which supports balancing between an amount of time for completing the conversion from the event-based simulation data to the cycle-based simulation data and data preservation in association with the conversion.

As described herein, systems and techniques are provided which support transforming the event-based simulation data (e.g., third party simulation data) associated with an event-based simulation tool to cycle-based simulation data associated with a cycle-based simulation tool. Waveforms included in the event-based simulation data are of a first format compatible with the event-based simulation tool, and waveforms included in the cycle-based simulation data are of a second format compatible with the cycle-based simulation tool. Descriptions herein of transforming the event-based simulation data to cycle-based simulation data, translating the event-based simulation data to cycle-based simulation data, converting the event-based simulation data to cycle-based simulation data, and mapping the event-based simulation data to cycle-based simulation data may be used interchangeably herein.

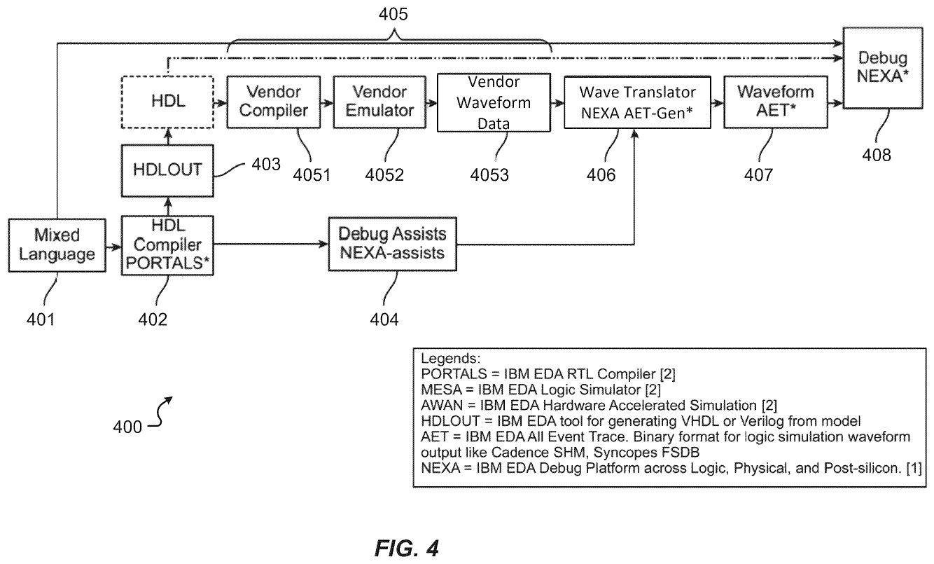

Example aspects of determining a sampling rate and applying the sampling rate in association with transforming the event-based simulation data to cycle-based simulation data are later described with reference to FIGS. 4, 5, 6, and 9.

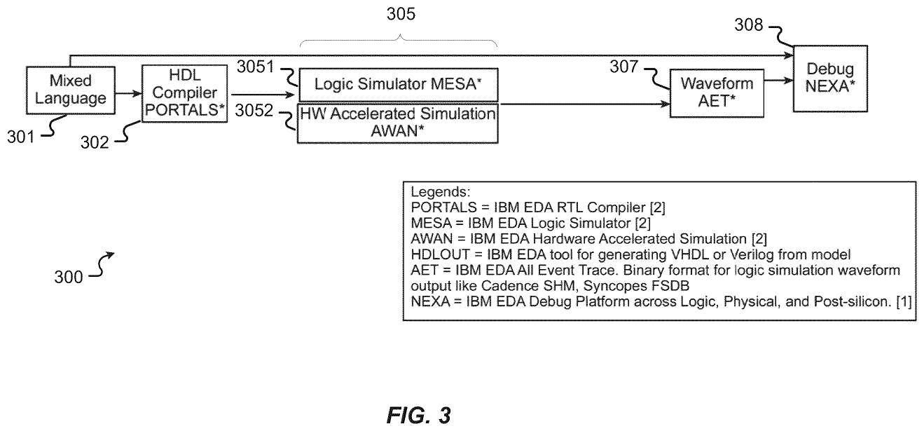

FIG. 3 depicts a flow diagram 300 supportive of hardware logic design and debug in accordance with one or more embodiments of the present disclosure.

With reference to flow diagram 300, a hardware design coded in a mixed language source code 301 (e.g., VHDL/Verilog) is compiled using an HDL compiler 302 (e.g., PORTALS, an IBM EDA RTL Compiler) and then simulated at 305 using a logic simulator 3051 (e.g., MESA, an IBM EDA Logic Simulator), and the simulation may be complemented with hardware accelerated simulation 3052 (e.g., using AWAN, IBM EDA hardware accelerated simulation). The simulation produces waveform data 307. The waveform data 307 may be include all event traces (AETs), which are logic simulation waveforms compatible for hardware logic debugging 308. AET format is a binary format for logic simulation waveform output such as, for example, Cadence SHM, Synopsys FSDB, and the like.

The flow diagram 300 is an example of cycle-based simulation and debugging of the cycle-based simulation.

In accordance with one or more embodiments of the present disclosure, the systems and techniques described herein support faster time-to-market of next generation systems through automatically mapping event-based simulation data to cycle-based simulation.

The systems and techniques described herein for automatically mapping event-based simulation data to cycle-based simulation overcome shortcomings due to a lack “plug-ins” of offerings from vendor companies (i.e., for faster co-debug of hardware/firmware and/or for emulation engine, RISCV-based designs) for translating or converting simulation data provided by the vendor companies. As will be described herein, the systems and techniques supported by aspects of the present disclosure provide a platform which is flexible and scalable for broader use-cases, while enabling highly efficient system logic debug.

Example aspects automatically mapping event-based simulation data to cycle-based simulation in hybrid hardware debug platforms are described herein with reference to FIGS. 4, 5, 6, and 9.

FIG. 4 depicts a flow diagram 400 illustrating a platform (e.g., a hybrid hardware debug platform) which supports automatically mapping event-based simulation data to cycle-based simulation in accordance with example aspects of the present disclosure. The platform and flow diagram 400 may include aspects of flow diagram 300 described herein, and repeated descriptions of like elements are omitted for brevity.

With reference to FIG. 4, mixed language source code 401 is combined and compiled in an HDL compiler 402. The HDL compiler 402 outputs a compiled design that is sent to a plug-in component 403 (HDLOUT) and from which debug assist elements 404 are generated. The plug-in component 403 (HDLOUT) may generate hardware description language (HDL) code (e.g., Verilog) for the hardware design. The HDL code is fed into vendor emulation flow 405 which in turn outputs a vendor waveform (included in vendor waveform data 4053) for specific hardware/firmware co-debug use cases.

The vendor emulation flow 405 is unique for each vendor and can include a vendor compiler 4051, a vendor emulator 4052 (also referred to herein as a vendor waveform generator), and vendor waveform data 4053 (also referred to herein as vendor proprietary waveform data). The vendor waveform data 4053 is output to wave translator 406. Based on the vendor waveform data 4053 and using debug assist elements 404, the wave translator 406 may generate waveform data 407 for use in debug operations 408.

Accordingly, for example, the wave translator 406 may generate the waveform data 407, with additional instrumentation assists, using a set of plug-ins in the framework of the platform. Aspects of the waveform data 407 provided by the waveform data 407 support effective debugging of AETs from emulation fails.

In an example, the vendor emulator 4052 may be an event-based simulator, and the vendor waveform data 4053 may include waveforms of signals generated based by the vendor emulator 4052. The waveforms may correspond to different signals associated with event-based simulation performed by the vendor emulator 4052. The wave translator 406 may transform the vendor waveform data 4053 to waveform data 407 using mapping and translation techniques described herein. The waveform data 407 may include waveforms which correspond to a cycle-based simulation format supported by the debug operations 408. For example, the waveform data 407 may be of a format (e.g., AET format, a binary format) compatible with a cycle-based simulation environment.

In an operational scenario, a hardware RTL can be a given VHDL along with notable portions of design based on Verilog™. A main simulation framework can be based on a given logic simulator, complemented with hardware-accelerated simulation capability to generate simulation waveforms. Since debug operations for select complex and full-system level scenarios may require fast interoperation of hardware/firmware system components, emulation platforms from vendors can be used as additional engines to complement hardware verification. Verilog™ code, for example, is generated using the plug-in component 403 and is fed into the vendor emulation flow 405 for specific hardware/firmware co-debug use cases. Waveforms generated in vendor proprietary form may be transformed into original HDL-friendly waveforms by the wave translator 406, with additional instrumentation assists from the debug assist elements 404, using a set of new plug-ins.

Aspects of the wave translator 406 may be implemented for example, by all or a subset of the computing environment 100 of FIG. 1. For example, the wave translator 406 may be implemented by or be an example of translation engine 150 of FIG. 1.

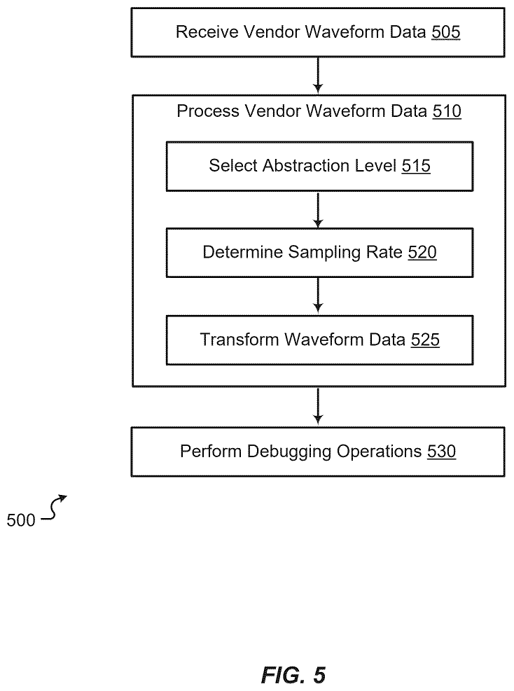

FIG. 5 illustrates an example flowchart of a method 500 that supports automatically mapping event-based simulation data to cycle-based simulation in hybrid hardware debug platforms in accordance with one or more embodiments of the present disclosure.

Aspects of the method 500 can be implemented, for example, by all or a subset of the computing environment 100 of FIG. 1 or platform of FIG. 4. For example, aspects of the method 500 may be implemented by the translation engine 150 of FIG. 1 or the wave translator 406 of FIG. 4.

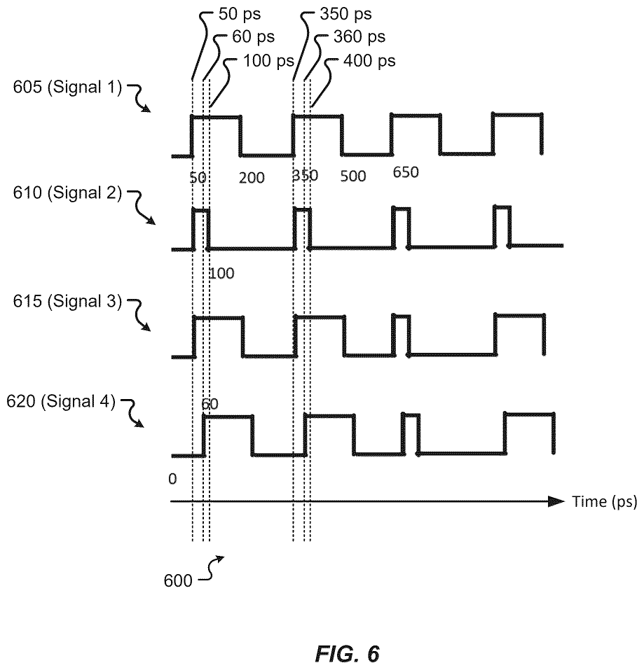

At 505, the method 500 includes receiving vendor waveform data 4053. The vendor waveform data 4053 may be event-based simulation data having events at specific timestamps. The vendor waveform data 4053 may include signal waveforms (e.g., signal waveform 605 through signal waveform 620 later described with reference to FIG. 6) associated with the event-based simulation. The event-based simulation data differs from cycle-based simulation data, in that cycle-based simulation data has transitions at a “simtick” granularity.

At 510, the method 500 includes processing the vendor waveform data 4053. Processing the vendor waveform data 4053 may be based on a sampling rate associated with transforming the vendor waveform data 4053 to the waveform data 407. Aspects of processing the vendor waveform data 4053 are described with reference to 515 through 525.

At 515, the method 500 includes selecting an abstraction level associated with sampling the vendor waveform data 4053, based on a target performance parameter (or multiple target performance parameters). For example, the method 500 may include determining the abstraction level based on a temporal parameter and a data preservation parameter (e.g., data loss, preservation of skew information) associated with transforming the vendor waveform data 4053 into the waveform data 407.

In an example, the temporal parameter may be a target time constraint (e.g., a target temporal duration, a threshold temporal duration) associated with transforming the vendor waveform data 4053 into the waveform data 407. In an example, the data preservation parameter may be associated with preserving or omitting skew information among signal waveforms comprised in the vendor waveform data 4053.

At 520, the method 500 includes determining the sampling rate based on the abstraction level. For example, the method 500 may include automatically determining the sampling rate based on processing the vendor waveform data 4053 in accordance with the abstraction level.

In some aspects, processing the vendor waveform data 4053 in accordance with the abstraction level may include implementing one or more processing operations specific to the abstraction level for calculating the sampling rate. The method 500 may support multiple candidate abstraction levels (e.g., level 1, level 2, level 3). Examples of determining the sampling rate based on the abstraction levels are later described herein with reference to FIG. 6.

In some aspects, the method 500 includes calculating a sampling rate that can be treated as “simtick” equivalent in a cycle-based simulation environment.

At 525, the method 500 includes transforming the vendor waveform data 4053 into waveform data 407 (cycle-based simulation data) based on the sampling rate determined at 520. Transforming the vendor waveform data 4053 may include transforming vendor waveforms (signal waveforms associated with event-based simulation) included in the vendor waveform data 4053 to logic simulation waveforms compatible with a hardware design language (HDL) for hardware logic debugging. For example, transforming the vendor waveform data 4053 may include transforming the vendor waveforms (signal waveforms) included in the vendor waveform data 4053 to waveforms of a cycle-based simulation format (e.g., a binary format, AET format) supported by the debug operations 408 and a cycle-based simulation environment.

At 530, the method 500 includes performing debugging operations (e.g., by debug operations 408) based on the waveform data 407. For example, the method 500 may include performing a debugging operation by processing the waveform data 407 within the cycle-based simulation environment.

FIG. 6 illustrates an example timing diagram 600 associated with automatically mapping event-based simulation data to cycle-based simulation in hybrid hardware debug platforms in accordance with one or more embodiments of the present disclosure. In the example of FIG. 6, time is in picoseconds (ps). Aspects of determining a sampling rate (e.g., at 520 of the method 500 of FIG. 5) based on abstraction level are now described with reference to the timing diagram 600 of FIG. 6.

In an example, signal waveform 605 through signal waveform 620 respectively correspond to signals (e.g., Signal 1 through Signal 4) associated with an event-based simulation (e.g., an event-based simulation performed by vendor emulator 4052). Signal waveform 605 through signal waveform 620 may be included in the vendor waveform data 4053 described with reference to FIG. 4. It is to be understood that the vendor waveform data 4053 is not limited to signal waveform 605 through signal waveform 620 illustrated in FIG. 6, and the vendor emulation flow 405 may include signal waveforms (not illustrated) additional or alternative to signal waveform 605 through signal waveform 620.

Abstraction Level 1: Determining the sampling rate according to Abstraction Level 1 may include checking the first few events of each signal (e.g., Signal 1, Signal 2, and the like) and using the smallest amount of time between two consecutive events of the same signal as the sampling rate. In some aspects, determining the sampling rate according to Abstraction Level 1 assumes (includes an assumption) that a fastest clock among the signals can be used as the sampling rate.

In an example of determining the sampling rate according to Abstraction Level 1 with reference to FIG. 6, the wave translator 406 may check the first three events (e.g., uptick, downtick, uptick) of each signal (e.g., Signal 1 through Signal 4), starting at 0 ps to a time point (e.g., 400 ps) such that the time window includes the first three events of each signal waveform. The wave translator 406 determines that, among Signal 1 through Signal 4, the smallest amount of time between two consecutive events of the same signal is 50 ps. For example, the wave translator 406 determines that the smallest amount of time between two consecutive events of the same signal is the difference of 50 ps between an uptick of Signal 2 at 50 ps and a downtick of Signal 2 at 100 ps. e.g., 100 ps−50 ps=50 ps.

It is to be understood that references to processing or analyzing a signal (e.g., Signal 1) includes processing or analyzing a signal waveform (e.g., signal waveform 605) correspond to the signal.

In some aspects, the amount of time associated with determining the sampling rate (also referred to herein as a scale factor) in accordance with Abstraction Level 1 may be the smallest among Abstraction Level 1 through Abstraction Level 3. Transforming the vendor waveform data 4053 to the waveform data 407 using the sampling rate determined in accordance with Abstraction Level 1 may preserve most but not all of the transition data included in the vendor waveform data 4053. The amount of time associated with completing the transformation in accordance with Abstraction Level 1 may be the smallest among Abstraction Level 1 through Abstraction Level 3.

Abstraction Level 2: Determining the sampling rate according to Abstraction Level 2 may include checking all the events of each signal and using the smallest amount of time between two consecutive events of the same signal as the sampling rate. In some aspects, determining the sampling rate according to Abstraction Level 2 assumes (includes an assumption) that there is no skew between events across different signals.

In an example of determining the sampling rate according to Abstraction Level 2 with reference to FIG. 6, the wave translator 406 may check all events (e.g., uptick, downtick, uptick, and the like) of each signal (e.g., Signal 1 through Signal 4), starting at 0 ps through the end of the event-based simulation. The wave translator 406 determines that, among Signal 1 through Signal 4, the smallest amount of time between two consecutive events of the same signal is 50 ps. For example, the wave translator 406 determines that the smallest amount of time between two consecutive events of the same signal is the difference of 50 ps between an uptick of Signal 2 and a downtick of Signal 2 (e.g., respectively at 50 ps and at 100 ps, respectively at 350 ps and at 400 ps). e.g., 100 ps−50 ps=50 ps.

In some aspects, the amount of time associated with determining the sampling rate (also referred to herein as a scale factor) in accordance with Abstraction Level 3 may be greater than the amount of time for determining the sampling rate in accordance with Abstraction Level 1 and less than the amount of time for determining the sampling rate in accordance with Abstraction Level 3. Transforming the vendor waveform data 4053 to the waveform data 407 using the sampling rate determined in accordance with Abstraction Level 2 may preserve all of the transition data included in the vendor waveform data 4053, but not preserve the skew data included in the vendor waveform data 4053. The amount of time associated with completing the transformation in accordance with Abstraction Level 1 may be greater than the amount of time for completing the transformation in accordance with Abstraction Level 1 and less than the amount of time for completing the transformation in accordance with Abstraction Level 3.

Abstraction Level 3: Determining the sampling rate may include checking all the events among all signals and using the smallest amount of time between two events across different signals as the sampling rate. In some aspects, determining the sampling rate according to Abstraction Level 3 makes no assumptions and is the most generic of the Abstraction Level 1 through Abstraction Level 3. In some cases, determining the sampling rate according to Abstraction Level 3 may potentially result in a smaller sampling rate, which may increase or bloat the overall time associated with transforming the vendor waveform data 4053 to the waveform data 407.

In an example of determining the sampling rate according to Abstraction Level 3 with reference to FIG. 6, the wave translator 406 may check all events (e.g., uptick, downtick, uptick, and the like) among all signals (e.g., Signal 1 through Signal 4), starting at 0 ps through the end of the event-based simulation. The wave translator 406 determines that, among Signal 1 through Signal 4, the smallest amount of time between two events across different signals is 10 ps. For example, the wave translator 406 determines that the smallest amount of time between two events across different signals is the difference of 10 ps between an uptick of Signal 1 (e.g., at 50 ps, at 350 ps) and an uptick of Signal 4 (e.g., at 60 ps, at 360 ps). e.g., 60 ps-50 ps=10 ps, and 360 ps−350 ps=10 ps.

Additionally, or alternatively, the wave translator 406 may determine that, among Signal 1 through Signal 4, the smallest amount of time between two events across different signals is the difference of 10 ps between an uptick of Signal 1 (e.g., at 50 ps, at 350 ps), Signal 2 (e.g., at 50 ps, at 350 ps), or Signal 3 (e.g., at 50 ps, at 350 ps) and an uptick of Signal 4 (e.g., at 60 ps, at 360 ps).

In some aspects, the amount of time associated with determining the sampling rate (also referred to herein as a scale factor) in accordance with Abstraction Level 3 may be the largest among Abstraction Level 1 through Abstraction Level 3. Transforming the vendor waveform data 4053 to the waveform data 407 using the sampling rate determined in accordance with Abstraction Level 3 may preserve all transition data and all skew data included in the vendor waveform data 4053. The amount of time associated with completing the transformation in accordance with Abstraction Level 3 may be the largest among Abstraction Level 1 through Abstraction Level 3.

In a comparative example, transforming the vendor waveform data 4053 to the waveform data 407 may be implemented in which 1 ps is directly mapped to 1 simtick for a simulation time period of 1100 ps, and the resulting cycle-based simulation equivalent would have 1100 simticks.

In contrast, for example, determining the sampling rate and converting the vendor waveform data 4053 to waveform data 407 according to the techniques described herein may result in a reduced amount of simticks. For example, converting the vendor waveform data 4053 to the waveform data 407 using the 50 ps sampling rate determined according to Abstraction Level 1 or Abstraction Level 2 would result in 22 simticks, with a cost of losing skew information between Signal 4 and other signals. In a further example, converting the vendor waveform data 4053 to the waveform data 407 using the 10 ps sampling rate determined according to Abstraction Level 3 2 would result in 110 simticks, while preserving skew information between Signal 4 and other signals.

The sampling described herein may support transforming the vendor waveform data 4053 to waveform data 407 compatible with debug operations 408. That is, the sampling may support mapping or translating of the vendor waveform data 4053 to waveform data 407 compatible with debug operations 408, thus supporting effective debugging of event-based simulation data in a cycle-based simulation environment. Aspects of the transformation (i.e., mapping, translating) techniques described herein enable a logic team (e.g., logic hardware and firmware engineers) to obtain, from event-based simulation data (e.g., vendor waveform data 4053) provided by a vendor platform, waveform data (e.g., waveform data 407) in a format with which the logic team is familiar and which is mapped to a cycle-based simulation environment. The different abstraction levels support effective transformation in view of target performance parameters (e.g., amount of data preservation, amount of time for completing the transformation). Accordingly, for example, the transformation techniques described herein support effective debugging of an IC design for cases in which simulation results (e.g., vendor waveform data 4053) provided by a vendor are of a format which is not compatible with debugging tools (e.g., debug operations 408) used by a logic team.

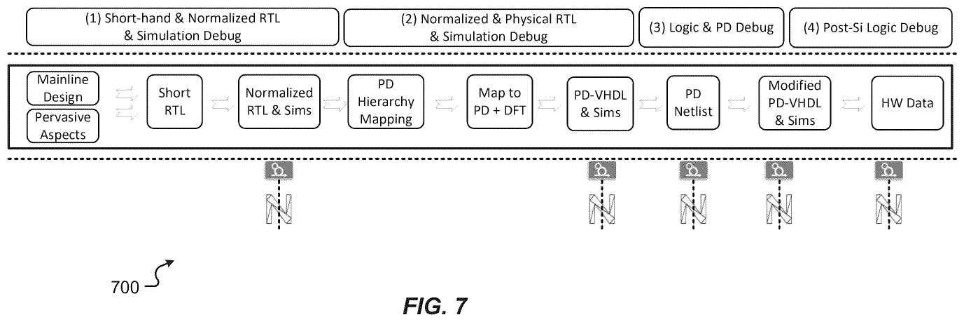

FIG. 7 illustrates an example workflow 700 associated with designing and debugging an IC design in accordance with one or more embodiments of the present disclosure. Aspects of the present disclosure support implementing the techniques described herein for automatically mapping event-based simulation data to cycle-based simulation at any stage of the workflow 700, as illustrated at FIG. 7.

The techniques described herein support providing a consistent platform and touchpoints to logic designers across different debug use cases including: a debug use case (1) which may involve working on short hand VHDL and normalized RTL/sims, a debug use case (2) which may involve physical design (PD) VHDL sims, a debug use case (3) which may involve emulation (e.g., PD netlist), and a debug use case (4) which may involve actual hardware data (e.g., post-silicon).

Accordingly, for example, the techniques described herein provide seamless integration of the framework of workflow 700 with event-based simulation data generated by vendor engines (e.g., Cadence), thus supporting consistent productivity improvement and continuous debug for the logic designer at various stages of the workflow 700.

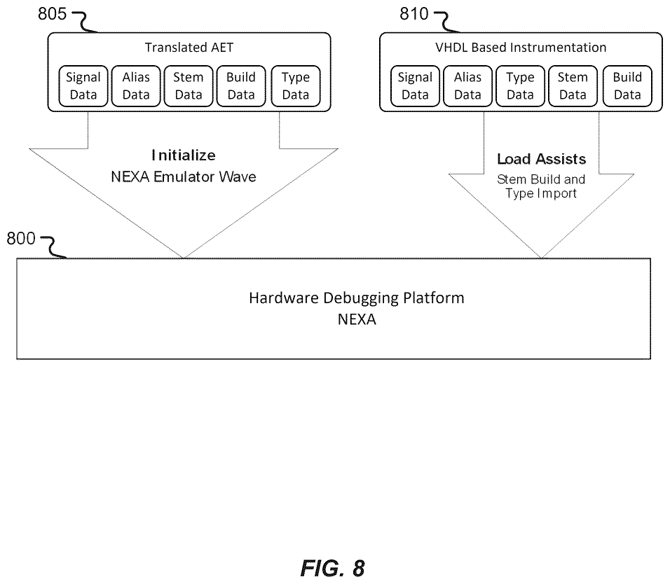

FIG. 8 illustrates an example of providing translated AET 805 and VHDL based instrumentation 810 to a hybrid hardware debugging platform 800 in accordance with one or more embodiments of the present disclosure.

The translated AET 805 is emulation Verilog-based AET. In general, an AET can have different kinds of information, as depicted by example sub-blocks ‘Signal data,’ ‘Alias data,’ ‘Stem data,’ ‘Build data,’, and ‘Type data.’ Signal data, refers to the different signals in the model and their corresponding signal values at different cycles. Alias data contains the IO port mapping information. Stem data contains the hierarchical information and the mapping to HDL source. Build data contains the build of materials information. Type data contains some of the HDL language constructs information, the language exotics such as, for example, the VHDL types. The emulation AET is HDLOUT generated Verilog-based AET.

The hybrid hardware debugging platform 800 supports merging together of the translated AET 805 and the VHDL based instrumentation 810. The hybrid hardware debugging platform 800 and translated AET 805 respectively include aspects of debug operations 408 and waveform data 407 described with reference to FIG. 4.

In an example implementation, for cases in which a designer is interested in signals and their values from an actual emulation AET, the hybrid hardware debugging platform 800 may enable the designer to look up the signals in the original VHDL that the designer had written. The techniques described herein support implementing VHDL based instrumentation 810 by importing the necessary information from a load assist 804 (debug assist AET) as shown in the right arrow. The debug assist AET is typically AET from logic simulation (e.g., MESA simulation) of the same HDL model. The merging d with reference to FIG. 8 enables logic designer experiences.

As described herein, embodiments of the present disclosure provide a hybrid hardware debug platform and support automatically mapping event-based simulation data to cycle-based simulation in the hybrid hardware debug platform. The platform may support complementary environments (e.g., logic design, block simulation, element simulation, system simulation, emulation). The platform supports debugging of signal waveforms and annotation of values of a given signal/cycle back to source level (e.g., mixed language, VHDL), which supports effective debugging based on the source level code. The platform supports high-level type and state enumeration.

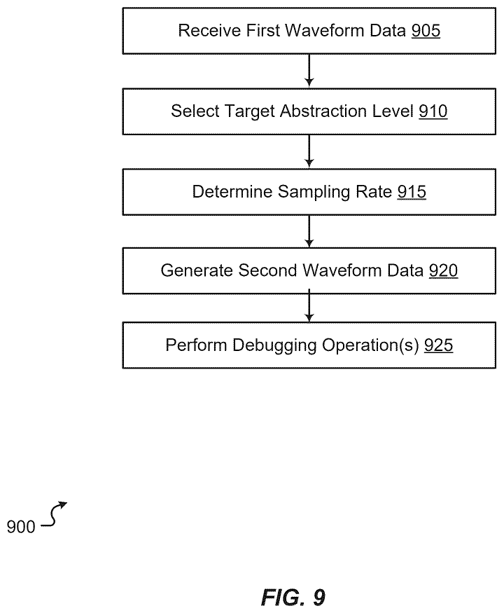

FIG. 9 illustrates an example flowchart of a method 900 that supports automatically mapping event-based simulation data to cycle-based simulation in hybrid hardware debug platforms in accordance with one or more embodiments of the present disclosure.

At 905, the method 900 includes receiving first waveform data of a first format, wherein the first waveform data includes event-based simulation data.

In some aspects, the method 900 includes: selecting (at 910) a target abstraction level from among a set of candidate abstraction levels associated with transforming the first waveform data to second waveform data, based on a parameter, wherein the parameter is selected from the group consisting of: a temporal parameter associated with transforming the first waveform data into the second waveform data; and a data preservation parameter associated with transforming the first waveform data into the second waveform data; and determining (at 915) a sampling rate based on the target abstraction level.

In some examples, the temporal parameter is a target temporal duration associated with transforming the first waveform data into the second waveform data.

In some examples, the data preservation parameter is associated with preserving skew information associated with signal waveforms included in the first waveform data.

In an example, determining the sampling rate is based on a first abstraction level among the set of candidate abstraction levels and includes: identifying, for at least two signal waveforms included in the first waveform data, a target quantity of events associated with each of the at least two signal waveforms; calculating, for each of the at least two signal waveforms included in the first waveform data, a temporal duration between two consecutive events included among the target quantity of events; and selecting, as the sampling rate, a smallest temporal duration among the temporal durations.

In an example, determining the sampling rate is based on a first abstraction level among the set of candidate abstraction levels and includes an assumption that a fastest clock among signal waveforms included in the first waveform data can be used as the sampling rate.

In an example, determining the sampling rate is based on a second abstraction level among the set of candidate abstraction levels and includes: identifying, for at least two signal waveforms included in the first waveform data, all events associated with each of the at least two signal waveforms; calculating, for each of the at least two signal waveforms included in the first waveform data, a temporal duration between two consecutive events included among all the events; and selecting, as the sampling rate, a smallest temporal duration among the temporal durations.

In an example, determining the sampling rate is based on a second abstraction level among the set of candidate abstraction levels and includes an assumption that there is no skew between events across signal waveforms included in the first waveform data.

In an example, determining the sampling rate is based on a third abstraction level among the set of candidate abstraction levels and includes: identifying, for at least two signal waveforms included in the first waveform data, all events associated each of the at least two signal waveforms; calculating temporal durations across events respectively associated with the at least two signal waveforms; and selecting, as the sampling rate, a smallest temporal duration among the temporal durations, wherein the smallest temporal duration is between a first event associated with a first signal waveform and a second event associated with a second signal waveform.

At 920, the method 900 includes generating second waveform data of a second format based on the first waveform data, wherein the second waveform data is compatible with a cycle-based simulation environment.

In some aspects, generating the second waveform data includes transforming the first waveform data to the second waveform data by sampling signal waveforms included in the first waveform data according to the sampling rate.

At 925, the method 900 includes performing one or more debugging operations by processing the second waveform data within the cycle-based simulation environment.

In the descriptions of the flowcharts herein, the operations may be performed in a different order than the order shown, or the operations may be performed in different orders or at different times. Certain operations may also be left out of the flowcharts, one or more operations may be repeated, or other operations may be added to the flowcharts.

Various embodiments are described herein with reference to the related drawings. Alternative embodiments can be devised without departing from the scope of the present disclosure. Various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. Moreover, the various tasks and process steps described herein can be incorporated into a more comprehensive procedure or process having additional steps or functionality not described in detail herein.

One or more of the methods described herein can be implemented with any or a combination of the following technologies, which are each well known in the art: a discrete logic circuit(s) having logic gates for implementing logic functions upon data signals, an application specific integrated circuit (ASIC) having appropriate combinational logic gates, a programmable gate array(s) (PGA), a field programmable gate array (FPGA), etc.

For the sake of brevity, conventional techniques related to making and using aspects of the present disclosure may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for purposes of illustration and description, but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagram or the steps (or operations) described therein without departing from the spirit of the disclosure. For instance, the actions can be performed in a differing order or actions can be added, deleted or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The present disclosure may be a system, a method, and/or a computer program product at any possible technical detail level of integration. The computer program product may include a computer readable storage medium (or media) having computer readable program instructions thereon for causing a processor to carry out aspects of the present disclosure.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present disclosure may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instruction by utilizing state information of the computer readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the present disclosure. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A computer-implemented method comprising:
receiving first waveform data of a first format, wherein the first waveform data comprises event-based simulation data;
generating second waveform data of a second format based on the first waveform data, wherein the second waveform data is compatible with a cycle-based simulation environment; and
performing one or more debugging operations by processing the second waveform data within the cycle-based simulation environment.

2. The computer-implemented method of claim 1, wherein generating the second waveform data comprises transforming the first waveform data to the second waveform data by sampling signal waveforms comprised in the first waveform data according to a sampling rate.

3. The computer-implemented method of claim 2, further comprising:
selecting a target abstraction level from among a set of candidate abstraction levels associated with transforming the first waveform data to the second waveform data, based on a parameter, wherein the parameter is selected from the group consisting of:
a temporal parameter associated with transforming the first waveform data into the second waveform data; and
a data preservation parameter associated with transforming the first waveform data into the second waveform data; and
determining the sampling rate based on the target abstraction level.

4. The computer-implemented method of claim 3, wherein determining the sampling rate is based on a first abstraction level among the set of candidate abstraction levels and comprises:
identifying, for at least two signal waveforms comprised in the first waveform data, a target quantity of events associated with each of the at least two signal waveforms;
calculating, for each of the at least two signal waveforms comprised in the first waveform data, a temporal duration between two consecutive events included among the target quantity of events; and
selecting, as the sampling rate, a smallest temporal duration among the temporal durations.

5. The computer-implemented method of claim 3, wherein determining the sampling rate is based on a first abstraction level among the set of candidate abstraction levels and includes an assumption that a fastest clock among signal waveforms comprised in the first waveform data can be used as the sampling rate.

6. The computer-implemented method of claim 3, wherein determining the sampling rate is based on a second abstraction level among the set of candidate abstraction levels and comprises:
identifying, for at least two signal waveforms comprised in the first waveform data, all events associated with each of the at least two signal waveforms;
calculating, for each of the at least two signal waveforms comprised in the first waveform data, a temporal duration between two consecutive events included among all the events; and
selecting, as the sampling rate, a smallest temporal duration among the temporal durations.

7. The computer-implemented method of claim 3, wherein determining the sampling rate is based on a second abstraction level among the set of candidate abstraction levels and includes an assumption that there is no skew between events across signal waveforms comprised in the first waveform data.

8. The computer-implemented method of claim 3, wherein determining the sampling rate is based on a third abstraction level among the set of candidate abstraction levels and comprises:
identifying, for at least two signal waveforms comprised in the first waveform data, all events associated each of the at least two signal waveforms;
calculating temporal durations across events respectively associated with the at least two signal waveforms; and
selecting, as the sampling rate, a smallest temporal duration among the temporal durations, wherein the smallest temporal duration is between a first event associated with a first signal waveform and a second event associated with a second signal waveform.

9. The computer-implemented method of claim 3, wherein the temporal parameter is a target temporal duration associated with transforming the first waveform data into the second waveform data.

10. The computer-implemented method of claim 3, wherein the data preservation parameter is associated with preserving skew information associated with signal waveforms comprised in the first waveform data.

11. A computing system having a memory having computer readable instructions and one or more processors for executing the computer readable instructions, the computer readable instructions controlling the one or more processors to perform operations comprising:
receiving first waveform data of a first format, wherein the first waveform data comprises event-based simulation data;
generating second waveform data of a second format based on the first waveform data, wherein the second waveform data is compatible with a cycle-based simulation environment; and
performing one or more debugging operations by processing the second waveform data within the cycle-based simulation environment.

12. The computing system of claim 11, wherein generating the second waveform data comprises transforming the first waveform data to the second waveform data by sampling signal waveforms comprised in the first waveform data according to a sampling rate.

13. The computing system of claim 12, wherein the computer readable instructions control the one or more processors to perform further operations comprising:
selecting a target abstraction level from among a set of candidate abstraction levels associated with transforming the first waveform data to the second waveform data, based on a parameter, wherein the parameter is selected from the group consisting of:
a temporal parameter associated with transforming the first waveform data into the second waveform data; and
a data preservation parameter associated with transforming the first waveform data into the second waveform data; and
determining the sampling rate based on the target abstraction level.

14. The computing system of claim 13, wherein:
determining the sampling rate is based on a first abstraction level among the set of candidate abstraction levels and comprises:
identifying, for at least two signal waveforms comprised in the first waveform data, a target quantity of events associated with each of the at least two signal waveforms;
calculating, for each of the at least two signal waveforms comprised in the first waveform data, a temporal duration between two consecutive events included among the target quantity of events; and
selecting, as the sampling rate, a smallest temporal duration among the temporal durations.

15. The computing system of claim 13, wherein determining the sampling rate is based on a first abstraction level among the set of candidate abstraction levels and includes an assumption that a fastest clock among signal waveforms comprised in the first waveform data can be used as the sampling rate.

16. The computing system of claim 13, wherein determining the sampling rate is based on a second abstraction level among the set of candidate abstraction levels and comprises:
identifying, for at least two signal waveforms comprised in the first waveform data, all events associated with each of the at least two signal waveforms;
calculating, for each of the at least two signal waveforms comprised in the first waveform data, a temporal duration between two consecutive events included among all the events; and
selecting, as the sampling rate, a smallest temporal duration among the temporal durations.

17. The computing system of claim 13, wherein determining the sampling rate is based on a second abstraction level among the set of candidate abstraction levels and includes an assumption that there is no skew between events across signal waveforms comprised in the first waveform data.

18. The computing system of claim 13, wherein determining the sampling rate is based on a third abstraction level among the set of candidate abstraction levels and comprises:
identifying, for at least two signal waveforms comprised in the first waveform data, all events associated each of the at least two signal waveforms;
calculating temporal durations across events respectively associated with the at least two signal waveforms; and
selecting, as the sampling rate, a smallest temporal duration among the temporal durations, wherein the smallest temporal duration is between a first event associated with a first signal waveform and a second event associated with a second signal waveform.

19. The computing system of claim 13, wherein:
the temporal parameter is a target temporal duration associated with transforming the first waveform data into the second waveform data; and
the data preservation parameter is associated with preserving skew information associated with signal waveforms comprised in the first waveform data.

20. A computer program product comprising a computer readable storage medium having program instructions embodied therewith, the program instructions executable by a processor to cause the processor to perform operations comprising:
receiving first waveform data of a first format, wherein the first waveform data comprises event-based simulation data;
generating second waveform data of a second format based on the first waveform data, wherein the second waveform data is compatible with a cycle-based simulation environment; and
performing one or more debugging operations by processing the second waveform data within the cycle-based simulation environment.
